(19) United States
(12) Patent Application Publication
(10) Pub. No.: US 2015/0171856 A1
(43) Pub. Date: Jun. 18, 2015

(54) INVERTER CHAIN CIRCUIT FOR CONTROLLING SHOOT-THROUGH CURRENT

(71) Applicant: SOONGSIL UNIVERSITY RESEARCH CONSORTIUM TECHNO-PARK, Seoul (KR)

(72) Inventors: Jin ho YOO, Gyeonggi-do (KR); Chang Kun Park, Gyeonggi-do (KR)

(21) Appl. No.: 14/571,225

(22) Filed: Dec. 15, 2014

(30) Foreign Application Priority Data
Dec. 16, 2013 (KR) 10-2013-0156648

(51) Int. Cl. H03K 17/16; H03F 1/02

(52) U.S. Cl. CPC H03K 17/162; H03F 1/0205; H03F 2200/372

(57) ABSTRACT

An inverter chain circuit for controlling a shoot-through current, including: first and second inverter chains to which input signals branched from an input port are individually applied, and in which inverters including N-type and P-type transistors are connected in multiple stages; a P-type first transistor in which an output signal of the first inverter chain is applied to a gate, a first terminal is connected to a first power supply, and a second terminal is connected to an output port; and an N-type second transistor in which an output signal of the second inverter chain is applied to a gate, a first terminal is connected to a second power supply lower than the first power supply, and a second terminal is connected to the output terminal.

### CROSS-REFERENCE TO RELATED APPLICATIONS

This application claims the priority of Korean Patent Application No. 10-2013-0156648 Dec. 16, 2013, in the Korean Intellectual Property Office, the disclosure of which is incorporated herein by reference.

### BACKGROUND OF THE INVENTION

1. Field of the Invention

The present invention relates to an inverter chain circuit for controlling a shoot-through current, and more particularly, to an inverter chain circuit for controlling a shoot-through current with which it is possible to improve efficiency of a system by minimizing a shoot-through current.

2. Description of the Related Art

In a general power amplifier, a power supply voltage needs to be constantly fixed. However, a polar transmitter that is recently developed minimizes power consumption in the power amplifier by allowing the power supply voltage to have the same magnitude as an envelope signal of an alternating input signal RF_{IN}. To achieve this, it is necessary to alter the power supply voltage to have the same magnitude of the envelope signal of the alternating input signal RF_{IN}.

FIG. 1 is a configuration diagram of a supply modulator for a general polar transmitter. The supply modulator is connected to a battery that outputs a fixed voltage, and serves to convert a voltage V_{BATTERY} output from the battery into an envelope voltage of an alternating input signal RF_{IN}.

FIG. 2 is a detailed diagram for describing input and output signals of the supply modulator illustrated in FIG. 1. A signal splitter is needed for the polar transmitter. The signal splitter generates a high-frequency signal θ(t) including phase information and an envelope signal R (t) from the alternating input signal RF_{IN}. Here, the high-frequency signal θ(t) is used as an input of the power amplifier, and the envelope signal R (t) is used as an input of the supply modulator.

FIG. 3 is a detailed diagram for describing the supply modulator illustrated in FIG. 2. The envelope signal is input to a class AB circuit, and output signals of the class AB circuit are input to a comparator via buffers. An output of the comparator is used as an input of a driver for driving a class-D chain. An operation principle of the supply modulator is already known, and, thus, the detailed description thereof will not be presented. An operation of the class-D chain will be described.

FIG. 4 is a circuit diagram illustrating a general class-D chain. As can be seen from its name, the class-D chain has a structure in which a plurality of class-D inverters is connected in a cascade manner, and refers to an inverter chain from an analogue viewpoint.

FIG. 4 illustrates an example where four class-D inverters D1, D2, D3 and D4 in total are connected in a cascade manner, and the number of class-D inverters may be different depending on designer's purpose. V_{IN} denotes an input voltage of the class-D chain output from the driver, and V_{OUT,D4} denotes an output voltage of the inverter D4 which is the final stage of the class-D chains.

The chain in which the plurality of class-D inverters are connected in the cascade manner is used to increase a final output power sequentially amplifying the V_{IN}, and is used when an impedance of a load connected to an output of the final stage (D4) of the class-D chain needs to be very low or the output of the final stage (D4) needs to be high. Accordingly, as a difference between an output power of the driver and an output power of the class-D chain is large, the number of class-D inverters constituting the class-D chain increases.

FIG. 5 is a diagram for describing a problem of the class-D chain according to the related art illustrated in FIG. 4. In FIG. 5, V_{IN}, D4 denotes a waveform of the input voltage of the final stage (D4) illustrated in FIG. 4. The input waveform of the class-D chain needs to be ideally a square wave, but a square wave having a certain slope (rising edge or falling edge) illustrated in FIG. 5 is actually generated.

As mentioned above, when the input waveform applied to the class-D chain rises or falls with a regular slope, a section (gray shaded portion) where a PMOS and an NMOS constituting the class-D inverter are simultaneously turned on appears. This reason is described as follows.

Of two transistors constituting the inverter D4 of FIG. 4, a PMOS located on an upper side is turned on when a signal of a threshold voltage V_{P,TH} or less is input, and an NMOS located on a lower side is turned on when a signal of a threshold voltage V_{N,TH} or more is input. Accordingly, the two transistors are turned on in the section where the input signal is equal to or higher than V_{N,TH} and is equal to or lower than V_{P,TH}.

As stated above, when the PMOS and NMOS are simultaneously turned on, a current flowing into a ground GND after sequentially passing through the PMOS and the NMOS from a power supply voltage V_{BATTERY}, that is, a shoot-through current, is caused. Since the shoot-through current is not a current supplied to the power amplifier but a current that is consumed in the class-D inverter, the shoot-through current causes a decrease in efficiency of the entire system. Since sizes of the PMOS and the NMOS are relatively larger than those in previous stages especially in the inverter D4 of FIG. 4 which is the final stage, power consumption by the shoot-through current is also largest. Naturally, shoot-through currents also exist at the previous stages D1, D2 and D3. In FIG. 4, the shoot-through currents flowing through the inverters D1, D2, D3 and D4 are expressed as I_{S,D1}, I_{S,D2}, I_{S,D3} and I_{S,D4}.

The polar transmitter described above is a structure suggested to increase power conversion efficiency of the entire system. When the polar transmitter is actually used, power conversion efficiency in the power amplifier can be improved, but the power conversion efficiency of the entire system is rarely improved due to power leakage of the supply modulator described above.

An example of the related art of the present invention includes Korean Patent Publication No. 2001-0015460 (published on Feb. 26, 2001).

### SUMMARY OF THE INVENTION

An aspect of the present invention provides an inverter chain circuit for controlling a shoot-through current with which it is possible to increase efficiency a power amplifier by minimizing a shoot-through current.

An aspect of the present invention also provides an inverter chain circuit for controlling a shoot-through current.

The inverter chain circuit includes: first and second inverter chains to which input signals branched from an input port are individually applied, and in which inverters including N-type and P-type transistors are connected in multiple stages; a P-type first transistor in which an output signal of the first inverter chain is applied to a gate, a first terminal is connected to a first power supply, and a second terminal is connected to an output port; and an N-type second transistor in which an output signal of the second inverter chain is applied to agate, a first terminal is connected to a second power supply lower than the first power supply, and a second terminal is connected to the output terminal. The first and second inverter chains are configured such that M (M is an integer equal to or greater than 2) numbers of inverters including inverters of a first group and inverters of a second group are alternately connected in a cascade manner, a size ratio of a P-type transistor to an N-type transistor is greater than a predetermined reference size ratio in the inverter of the first group, and the size ratio is smaller than the reference size ratio in the inverter of the second group. The inverter of the final stage in the first inverter chain is the inverter of the first group, and the inverter of the final stage in the second inverter chain is the inverter of the second group.

Here, the inverter chain circuit may further include a reference inverter that is disposed between the input port and the two inverter chains, and amplifies the input signals to respectively apply the amplified input signals to the first and second inverter chains. The reference inverter may include N-type and P-type transistors having the reference size ratio.

According to another aspect of the present invention, there is provided an inverter chain circuit for controlling a shoot-through current. The inverter chain circuit includes: an inverter chain that amplifies an input signal applied from an input port to output the amplified input signal, and includes reference inverters of multiple stages in which a size ratio of a P-type transistor to an N-type transistor is equal to a predetermined reference size ratio; a first inverter to which an output signal of the inverter chain is applied, and in which a size ratio of a P-type transistor to an N-type transistor is larger than the predetermined reference size ratio; a second inverter to which the output signal of the inverter chain is applied, and in which a size ratio of a P-type transistor to an N-type transistor is smaller than the reference size ratio; a P-type first transistor in which an output signal of the first inverter is applied to a gate, a first terminal is connected to a first power supply, and a second terminal is connected to an output port; and an N-type second transistor in which an output signal of the second inverter is applied to a gate, a first terminal is connected to a second power supply lower than the first power supply, and a second terminal is connected to the output port.

Here, the signal applied to the gate of the first transistor may have a duty of more than 0.5, and the signal applied to the gate of the second transistor may have a duty of less than 0.5.

Further, the size ratio of the first transistor to the second transistor may be equal to the reference size ratio.

According to still another aspect of the present invention, there is provided an inverter chain circuit for controlling a shoot-through current. The inverter chain circuit includes: an inverter chain stage that amplifies an input signal supplied from an input port to output the amplified input signal, and includes reference inverters of multiple stages in which a size ratio of a P-type transistor to an N-type transistor is equal to a predetermined reference size ratio; an inverter stage that amplifies the input signal to output the amplified input signal, and includes the reference inverter of one stage; a P-type first transistor in which an output signal of the inverter chain stage is applied to a gate, a first terminal is connected to a first power supply, and a second terminal is connected to an output port; and an N-type second transistor in which the output signal of the inverter stage is applied to a gate, a first terminal is connected to a second power supply lower than the first power supply, and a second terminal is connected to the output port.

According to still another aspect of the present invention, there is provided an inverter chain circuit for controlling a shoot-through current. The inverter chain circuit includes: a reference inverter that amplifies an input signal supplied from an input port to output the amplified input signal, and in which a size ratio of a P-type transistor to an N-type transistor is a predetermined reference size ratio; an inverter chain to which an output signal of the reference inverter is applied, and in which inverters including N-type and P-type transistors are connected in multiple stages; a

P-type first transistor in which an output signal of the inverter chain is applied to a gate, a first terminal is connected to a first power supply, and a second terminal is connected to an output port; and an N-type second transistor in which the output signal of the reference inverter is applied to a gate, a first terminal is connected to a second power supply lower than the first power supply, and a second terminal is connected to the output port. The inverter chain is configured such that M (M is an integer equal to or greater than 2) numbers of inverters including inverters of a first group and inverters of a second group are alternately connected in a cascade manner, a size ratio of a P-type transistor to an N-type transistor is greater than a predetermined reference size ratio in the inverter of the first group, and the size ratio is smaller than the reference size ratio in the inverter of the second group.

The inverter of the final stage in the inverter chain is the inverter of the first group.

Here, the signal applied to the gate of the first transistor may have a duty of more than 0.5.

Further, the size ratio of the first transistor to the second transistor may be equal to the reference size ratio.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration diagram of a supply modulator for a general polar transmitter;

FIG. 2 is a detailed diagram for describing input and output signals of the supply modulator illustrated in FIG. 1;

FIG. 3 is a detailed diagram for describing the supply modulator illustrated in FIG. 2;

FIG. 4 is a circuit diagram illustrating a general class-D chain;

FIG. 5 is a diagram for describing a problem of the class-D chain according to the related art of FIG. 4;

FIG. 6 is a configuration diagram of an inverter chain circuit according to a first exemplary embodiment of the present invention;

FIG. 7 illustrates input signals of two transistors in the configuration of the inverter chain of FIG. 6;

FIG. 8 illustrates an example of an operation graph of the inverter chain on a side of a first transistor of FIG. 6; and

FIGS. 9 to 12 are configuration diagrams of inverter chain circuits according to second to fifth exemplary embodiments of the present invention.

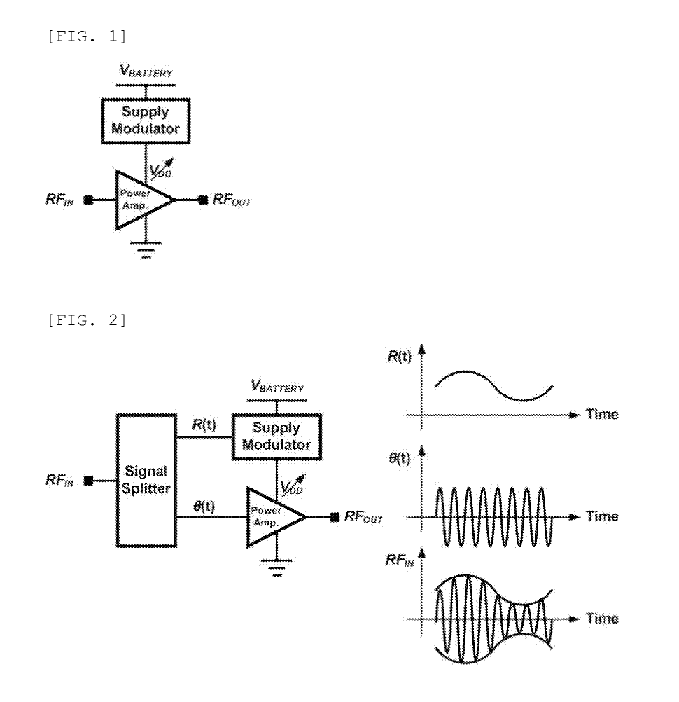

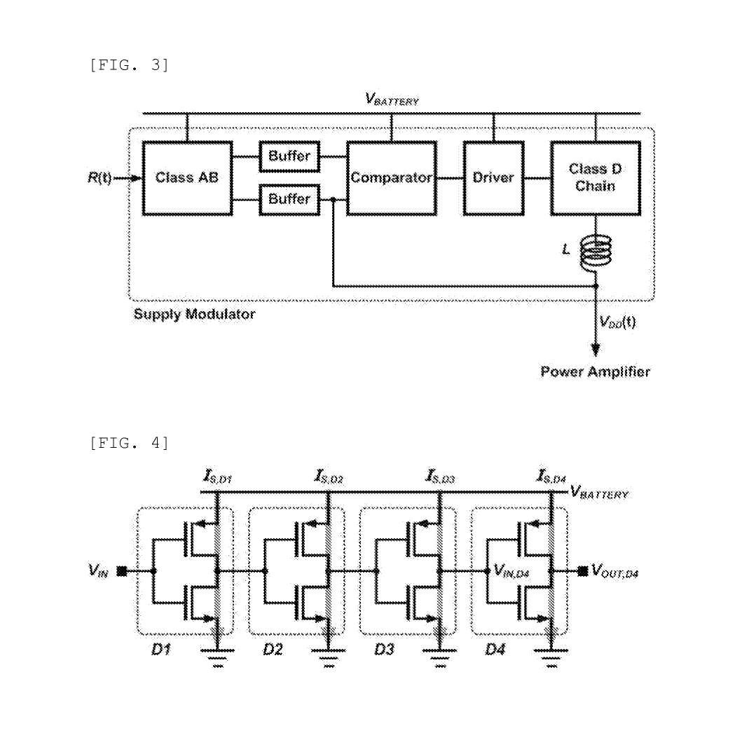

### DETAILED DESCRIPTION OF THE PREFERRED EMBODIMENT

Exemplary embodiments of the present invention will now be described in detail with reference to the accompanying drawings to allow those skilled in the art to easily implement the exemplary embodiments.

As set forth above, according to exemplary embodiments of the invention, in an inverter chain circuit for controlling a shoot-through current, a shoot-through current can be reduced, so that it is possible to increase efficiency of a power amplifier. Accordingly, it is possible to increase efficiency of the entire system.

Hereinafter, an inverter chain circuit capable of minimizing a shoot-through current will be described in detail. An inverter chain in the exemplary embodiment of the present invention refers to a class-D chain, and is referred to as an inverter chain for the sake of convenience in description. In the present exemplary embodiment, by splitting input signals of a PMOS and an NMOS constituting the inverter chain, a section where the PMOS and the NMOS are simultaneously turned on is minimized, and, thus, a shoot-through current is minimized.

In the present exemplary embodiment, as a kind of the transistor, a MOSFET (Metal Oxide Semiconductor Field Effect Transistor) is used. Naturally, the kind of the transistor is merely an example, and other transistors such as a BJT (Bipolar Junction Transistor) may be used.

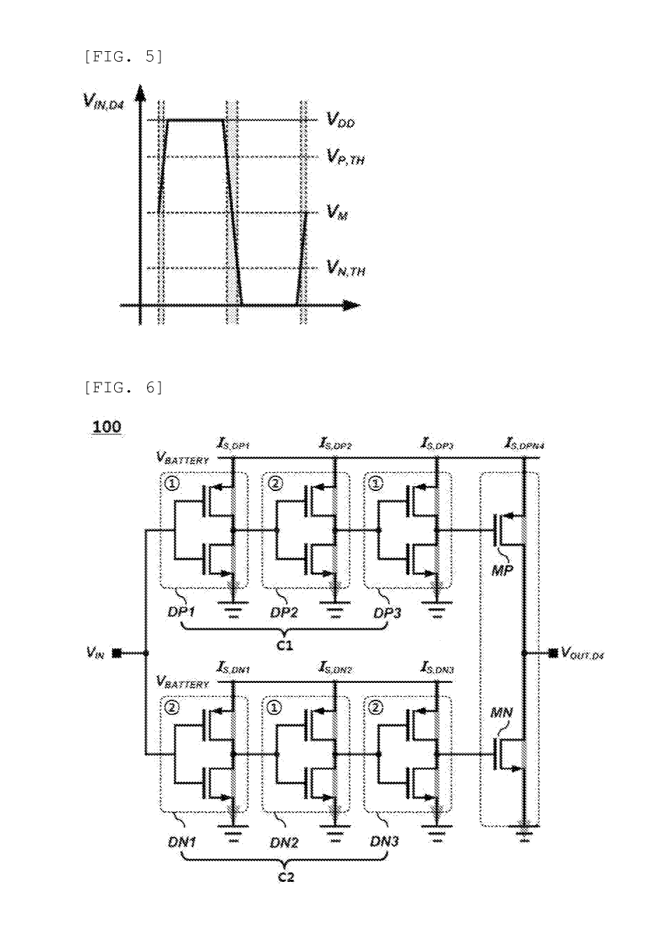

FIG. 6 is a configuration diagram of an inverter chain circuit according to a first exemplary embodiment of the present invention. Unlike the circuit according to the related art illustrated in FIG. 4, the inverter D1 is divided into inverters DP1 and DN1 in FIG. 6. Similarly, the inverter D2 is divided into inverters DP2 and DN2, and the inverter D3 is divided into inverters DP3 and DN3. Ultimately, the inverter DP3 drives a PMOS transistor MP, and the inverter DN3 drives an NMOS transistor MN. Consequentially, in FIG. 6, input waveforms of the transistors MP and MN can be independently formed to be different from each other.

The detail of the configuration of FIG. 6 is described as follows. An inverter chain circuit 100 according to the first exemplary embodiment of the present invention includes a first inverter chain C1, a second inverter chain C2, a P-type first transistor MP, and an N-type second transistor MN.

Here, input signals branched from an input port V_{IN} are respectively applied to the first inverter chain C1 and the second inverter chain C2, and the input signals are individually amplified to be respectively supplied to the first transistor MP and the second transistor MN. The inverter chain includes a plurality of inverters, and the signal input to the inverter chain is gradually amplified while passing through the inverters of the respective stages to be output.

In the first and second inverter chains C1 and C2, the plurality of inverters is connected in a cascade manner. The first inverter chain C1 includes the inverters DP1, DP2 and DP3 of three stages, and the second inverter chain C2 includes the inverters DN1, DN2 and DN3 of three stages. Here, the inverter has the same configuration of a general inverter including N-type and P-type transistors (NMOS, PMOS), and the detailed description thereof will not be presented.

An output signal of the first inverter chain C1 is applied to a gate of the first transistor MP which is the PMOS, and a first terminal of the first transistor is connected to a first power supply V_{BATTERY} and a second terminal thereof is connected to an output port V_{OUT,D4}. An output signal of the second inverter chain C2 is applied to a gate of the second transistor MN which is the NMOS, and a first terminal of the second transistor is connected to a second power supply GND lower than the first power supply V_{BATTERY} and a second terminal thereof is connected to the output port V_{OUT,D4}.

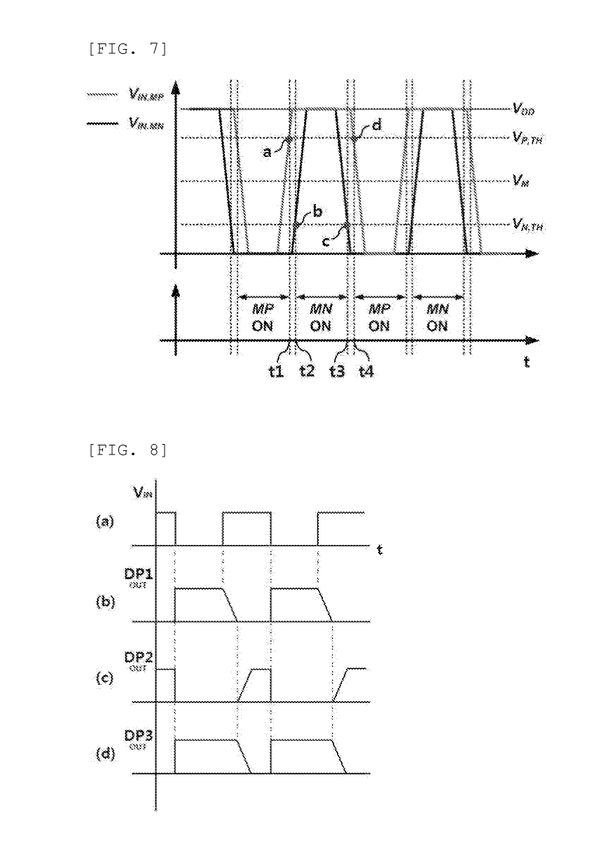

In the first exemplary embodiment, by allowing the inverters of the respective stages to have different size ratios between the N-type and P-type transistors included in the inverter, the first and second transistors MP and MN are prevented from being simultaneously turned on, and, thus, the shoot-through current is minimized. If the two transistors MP and MN are simultaneously turned on, a current flows into the ground GND after sequentially passing through the first transistor MP and the second transistor MN from the V_{BATTERY} VDD, and this current is a shoot-through current. The detailed description thereof is referred to the description of FIG. 5.

In FIG. 6, \textcircled{1} assigned to the inverter denotes an inverter of a first group, and \textcircled{2} denotes an inverter of a second group. The inverter \textcircled{1} of the first group refers to an inverter in which a size ratio of the P-type transistor to the N-type transistor is larger than a predetermined reference size ratio. In such a case, the P-type transistor has strength higher than the N-type transistor.

In contrast, the inverter \textcircled{2} of the second group refers to an inverter in which the size ratio of the P-type transistor to the N-type transistor is smaller than the reference size ratio. In this case, the N-type transistor has strength higher than the P-type transistor.

Here, the reference size ratio refers to a size ratio for allowing the N-type transistor and the P-type transistor to have the same performance (characteristics). In generally, when the size ratio of the P-type transistor to the N-type transistor is 2.5:1, the two transistors have the same performance (characteristics), and the detailed description thereof will be presented below.

As an example, when the size ratio of the P-type transistor to the N-type transistor is 4:1 in the inverter, the size of the P-type transistor is relatively larger than when the transistors have the reference size ratio of 2.5:1, and the inverter having such a size ratio may correspond to the first group. Further, when the size ratio of the P-type transistor to the N-type transistor is 1:1, the size of the P-type transistor is relatively smaller than when the two transistors have the reference size ratio of 2.5:1, and the inverter having such a size ratio may correspond to the second group.

Referring again to FIG. 6, the first and second inverter chains C1 and C2 are configured such that M (M is an integer equal to or greater than 2) numbers of inverters including the inverter \textcircled{1} of the first group and the inverter \textcircled{2} of the second group are alternately connected. FIG. 6 illustrates an example of M=3.

Here, regardless of a number of M, in the first inverter chain C1, the inverter of the final stage may be the inverter \textcircled{1} of the first group in which the P-type transistor has strength higher than the N-type transistor. For example, when M=2, inverters of two stages are present in the first inverter chain, and the inverter of the first stage may be the inverter of the second group and the inverter of the second stage may be the inverter of the first group. Similarly, regardless of a number of M, in the second inverter chain C2, the inverter of the final stage may be the inverter \textcircled{2} of the second group.

The strength of the transistor is a factor related to a channel resistance, and the channel resistance is determined by the size of the transistor. When the size of the transistor become large, the channel resistance decreases, and the strength (performance) of the transistor increases.

However, in general, since the PMOS has mobility lower than the NMOS, the size of the PMOS needs to be approximately 2.5 times larger than the size of the NMOS in order to allow the PMOS and the NMOS to have the same channel resistance (performance). Hereinafter, it is assumed that the size ratio of the first transistor MP serving as the PMOS to the second transistor MN serving as the NMOS which are illustrated in FIG. 6 is 2.5:1. That is, it is assumed that the first and second transistors have the reference size ratio and have the same strength.

In contrast, as stated above, in the inverter \textcircled{1} of the first group in which the P-type transistor has strength higher than the N-type transistor, it is assumed that the size ratio of the P-type transistor to the N-type transistor constituting the inverter \textcircled{1} have 4:1. In the inverter \textcircled{2} of the second group in which the P-type transistor has a strength lower than the N-type transistor, it is assumed that the size ratio of the P-type transistor to the N-type transistor is 1:1. Naturally, even though the size ratio between the transistors is 1:1, it is apparent that the strength of the P-type transistor is more decreased than that of the N-type transistor due to an actual mobility difference between the PMOS and the NMOS.

Hereinafter, a process of minimizing the shoot-through current will be described based on the aforementioned description. FIG. 7 illustrates input signals of the first and second transistors in the configuration of the inverter chain of FIG. 6.

In FIG. 7, V_{IN,MP} denotes an input signal of the first transistor MP, and V_{IN,MN} denotes an input signal of the second transistor MN. V_{P,TH} denotes a threshold voltage of the first transistor MP, and V_{N,TH} denotes a threshold voltage of the second transistor MN. Here, the first transistor MP is turned on when an input signal of V_{P,TH} or less is input, and the second transistor MN is turned on when an input signal of V_{N,TH} or more is input.

In conclusion, in the present exemplary embodiment, the input signals input to the two transistors MP and MN can be individually generated as the V_{IN,MP} and the V_{IN,MN}, as illustrated in FIG. 7. Duties thereof are also different from each other. Accordingly, the two transistors are prevented from being simultaneously turned on. The principle thereof is described as follows.

In order to prevent the two transistors MP and MN from being simultaneously turned on, an input waveform applied to the gate of the first transistor MP needs to have a duty of more than 0.5, and an input waveform applied to the gate of the second transistor MN needs to have a duty of less than 0.5. A difference between the duties can be seen from FIG. 7.

As illustrated on a lower side of FIG. 7, it can be seen that sections where the first transistor MP is turned on and sections where the second transistor MN is turned on are not overlapped with each other and a time difference is present in the sections where the two transistors are turned on. An input signal of V_{P,TH} or more is applied to the first transistor MP at a time point of t1, and the first transistor MP is turned off. An input signal of V_{N,TH} or more is applied to the second transistor MN at a time point of t2, and the second transistor MN is turned on. That is, after the first transistor MP is turned off, the second transistor MN is turned on.

An input signal of V_{N,TH} or less is applied to the second transistor MN at a time point of t3, and the second transistor MN is turned off. An input signal of V_{P,TH} or less is applied to the first transistor MP, and the first transistor MP is turned on. That is, after the second transistor MN is turned off, the first transistor MP is turned on.

The reason why the duty of the signal input to the transistor is adjusted is related to the configuration of the inverter chain disposed at the previous stage of the transistor. In FIG. 6, in order to allow the input waveform of the first transistor MP to have a duty of 0.5 or more, the sizes of the NMOSs and the PMOSs constituting the inverters DP1, DP2 and DP3 that drive the first transistor may be adjusted. When the strength of the PMOS is adjusted to be higher than the NMOS in the inverter DP3, the strength of the NMOS is adjusted to be higher than the PMOS in the inverter DP2, and the strength of the PMOS is adjusted to be higher than the NMOS in the inverter DP1, it is possible to obtain a duty of 0.5 or more. Here, the strength being higher means that the size of the transistor is more increased to reduce a channel resistance component.

In contrast, in order to allow the input waveform of the second transistor MN to have a duty of 0.5 or less, the sizes of the NMOSs and the PMOSs constituting the inverters DN1, DN2 and DN3 that drive the second transistor maybe adjusted. When the strength of the NMOS is adjusted to be higher than the PMOS in the inverter DN3, the strength of the PMOS is adjusted to be higher than the NMOS in the inverter DN2, and the strength of the NMOS is adjusted to be higher than the PMOS in the inverter DN1, it is possible to obtain a duty of 0.5 or less.

FIG. 8 illustrates an example of an operation graph of the inverter chain on a side of the first transistor of FIG. 6. (a) of FIG. 8 depicts an input signal V_{IN} applied to the inverter DP1, (b) of FIG. 8 depicts a signal DP1_{OUT} which is output from the inverter DP1 and is applied to the inverter DP2, (c) of FIG. 8 depicts a signal DP2_{OUT} which is output from the inverter DP2 and is applied to the inverter DP3, and (d) of FIG. 8 depicts a signal DP3_{OUT} which is output from the inverter DP3 and is applied to the first transistor MP.

As stated above, it is described that the size ratio of the P-type transistor to the N-type transistor in the inverters DP1 and DP3 serving as the inverters of the first group is 4:1, and the size ratio of the P-type transistor to the N-type transistor in the inverter DP2 serving as the inverter of the second group is 1:1. Referring to FIG. 8, it can be seen that a duty of a signal becomes large as the signal passes through the inverters.

If the three inverters DP1 to DP3 are the inverters of the first group, since a duty of a final output signal returns to an original form depicted in (a) of FIG. 8, such a configuration is not proper. Accordingly, in order to adjust the duty, the inverter chain needs to be configured such that the inverters of the first group and the second group are alternately connected, as in the present exemplary embodiment. Naturally, as the stage number of the inverters constituting the inverter chain increases, there may be a large duty difference. When the stage number of the inverters is two, there is a smaller duty difference than when the stage number of the inverters is three. That is, such a principle is applicable to two stages or three or more stages other than the three stages.

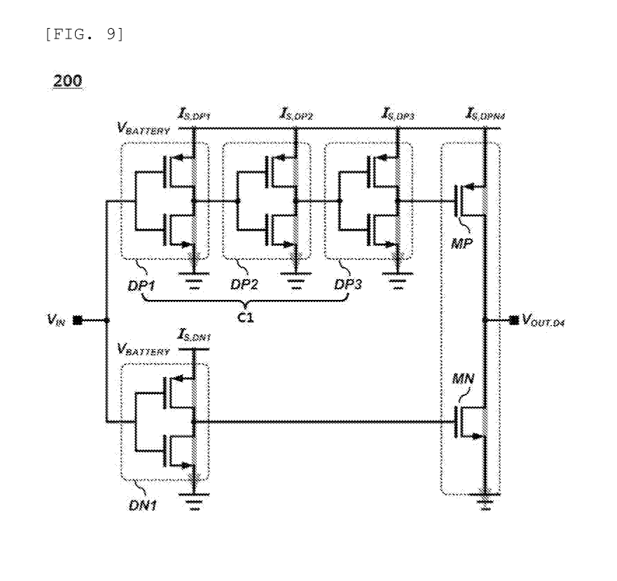

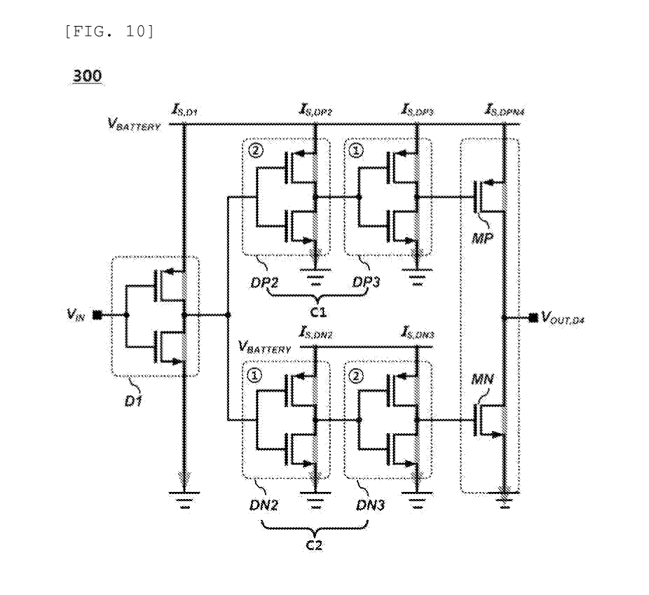

FIG. 9 is a configuration diagram of an inverter chain circuit according to a second exemplary embodiment of the present invention. An inverter chain circuit 200 according to the second exemplary embodiment includes an inverter chain stage C1, an inverter stage DN1, a P-type first transistor MP, and an N-type second transistor MN.

Unlike the first exemplary embodiment of FIG. 6, in FIG. 9, inverters of three stages are connected to the transistor MP, and an inverter of one stage is connected to the transistor MN. These inverters are reference inverters in which the NMOS and the PMOS have the same performance (characteristics). The transistors MP and MN have the reference size ratio and the same performance.

Firstly, in the inverter chain stage C1, reference inverters DN1, DN2 and DN3 in which the size ratio of the P-type transistor to the N-type transistor is equal to a predetermined reference size ratio are connected in multiple stages. The inverter stage is implemented as a reference inverter DN1 of one stage. Here, the reference inverter may be implemented by allowing the size ratio of the PMOS transistor to the NMOS transistor to be 2.5:1.

Input signals branched from the input port V_{IN} are respectively applied to the inverter chain stage C1 and the inverter stage DN1, and the input signals are individually amplified to be respectively applied to the first transistor MP and the second transistor MN.

An output signal of the inverter chain stage C1 is applied to a gate of the first transistor MP serving as a PMOS, and a first terminal of the first transistor is connected to a first power supply V_{BATTERY} and a second terminal thereof is connected to an output port V_{OUT,D4}. An output signal of the inverter stage DN1 is applied to a gate of the second transistor MN serving as an NMOS, and a first terminal of the second transistor is connected to a second power supply GND lower than the first power supply V_{BATTERY} and a second terminal thereof is connected to the output port V_{OUT,D4}.

Hereinafter, an operation of the configuration according to the second exemplary embodiment will be described. In general, since mobility of the PMOS is lower than the NMOS, the size ratio of the PMOS to the NMOS needs to be approximately 2.5:1 in order to allow the two transistors to have the same perform, as described above. In this case, an input impedance of the PMOS is more decreased than an input impedance of the NMOS. When such a principle is similarly applied to the first and second transistors MP and MN of FIG. 9, since the input impedance of the transistor MP has a value smaller than the input impedance of the transistor MN, a power for driving the transistor MP needs to have a value larger than a power for driving the transistor MN.

Accordingly, the inverters DP1, DP2 and DP3 are needed to normally drive the transistor MP, whereas even though only the inverter DN1 is needed to normally drive the transistor MN, the transistor MN can be driven at the same level as the transistor MP. Unlike the first exemplary embodiment of FIG. 6, in FIG. 9, since the inverters DN2 and DN3 are not provided, the shoot-through currents I_{S,DN2} and I_{S,DN3} generated in the inverters DN2 and DN3 are not generated. Accordingly, in terms of the entire system, power consumption can be reduced, the circuit can be more simplified, and an area of the circuit can also be reduced.

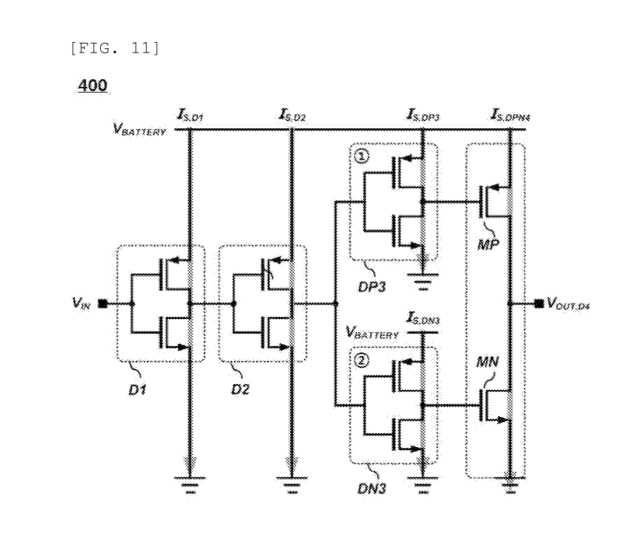

FIG. 10 is a configuration diagram of an inverter chain circuit according to a third exemplary embodiment of the present invention. An inverter chain circuit 300 according to the third exemplary embodiment includes a reference inverter D1, a first inverter chain C1, a second inverter chain C2, a P-type first transistor MP, and an N-type second transistor MN.

FIG. 10 illustrates a modification example of FIG. 6. The inverter chains C1 and C2 are not the inverters of three stages of FIG. 6 but inverters of two stages, and the reference inverter D1 is disposed instead of the other one stage. As described above, the reference inverter may be implemented by allowing the size ratio of the PMOS to the NMOS to be approximately 2.5:1. Similarly to the first exemplary embodiment, it is assumed that the size ratio of the first transistor MP to the second transistor MN is 2.5:1 and the two transistors have the same strength.

The reference inverter D1 of FIG. 10 is disposed between an input port V_{IN} and the two inverter chains C1 and C2, and amplifies input signals to individually apply the amplified input signals to the first and second inverter chains C1 and C2. The third exemplary embodiment is the same as the first exemplary embodiment except for a modification of an input stage.

As mentioned above, as compared to FIG. 6, in FIG. 10, since the inverter of the first stage is implemented as one inverter without being divided into two inverters, the entire circuit configuration is more simplified than that of FIG. 6. In this case, input waveforms for preventing the shoot-through currents between the first and second transistors MP and MN may be generated by adjusting the size ratio of the PMOS to the NMOs constituting the inverters DP2, DP3, DN2 and DN3, as in the first exemplary embodiment.

FIG. 11 is a configuration diagram of an inverter chain circuit according to a fourth exemplary embodiment of the present invention. An inverter chain circuit 400 according to the fourth exemplary embodiment includes first and second reference inverters D1 and D2, first and second inverters DP3 and DN3, a P-type first transistor MP, and a N-type second transistor MN.

The first and second reference inverters D1 and D2 amplify input signals supplied from an input port V_{IN} to output the amplified input signals, and are connected in a cascade manner to form an inverter chain. Here, the number of reference inverters may be two or more.

An output signal of the inverter chain, that is, an output signal of the second reference inverter D2, is applied to the first inverter DP3. The first inverter DP3 is an inverter \textcircled{1} of a first group in which a size ratio of a P-type transistor to an N-type transistor is greater than a reference size ratio, and strength of the P-type transistor is higher than the N-type transistor. To achieve this, the size ratio of the P-type transistor to the N-type transistor may be 4:1.

The output signal of the second reference inverter D2 is applied to the second inverter DN3. The second inverter DN3 is an inverter \textcircled{2} of a second group in which the size ratio of the P-type transistor to the second transistor is smaller than the reference size ratio, and the strength of the N-type transistor is higher than the P-type transistor. To achieve this, the size ratio of the P-type transistor to the N-type transistor may be 1:1.

An output signal of the first inverter DP3 is applied to a gate of the first transistor MP serving as a PMOS, and a first terminal of the first transistor is connected to a first power supply V_{BATTERY} and a second terminal thereof is connected to an output port V_{OUT,D4}. An output signal of the second inverter DN3 is applied to a gate of the second transistor MN serving as an NMOS, and a first terminal of the second transistor is connected to a second power supply GND lower than the first power supply V_{BATTERY} and a second terminal thereof is connected to the output port V_{OUT,D4}. The size ratio of the first transistor MP to the second transistor MN is 2.5:1. That is, it is assumed that the first and second transistors MP and MN have the reference size ratio and the two transistors have the same strength.

With such configurations of the two inverters DP3 and DM3, the signal applied to the gate of the first transistor MP can be driven with a duty of more than 0.5, and the signal applied to the gate of the second transistor MN can be driven with a duty of less than 0.5. Accordingly, it is possible to obtain an effect similar to that of FIG. 7. However, a duty difference between the waveforms input to the two transistors may be more decreased than that in FIG. 7. That is, a distance between t1 and t2 and a distance between t3 and t4 may be more decreased than those in FIG. 7.

The fourth exemplary embodiment described above is a modification example of the third exemplary embodiment of FIG. 10 and is an example where only the inverters DP3 and DN3 are used as the inverter chains divided to form the input waveforms of the first and second transistors MP and MN to be different from each other. In this case, unlike the exemplary embodiments of FIGS. 6 and 10, drive stages of the inverters D1 and D2 are used in common by the transistors MP and MN, and the inverters DP3 and DN3 are used as individual drive stages for forming the input waveforms of the transistors MN and MP to be different from each other.

As compared to FIGS. 6 and 10, in FIG. 11, it is possible to more simplify the circuit. Naturally, in terms of easily forming the input waveforms of the transistors MP and MN to be different from each other, the circuit of FIG. 10 is superior to that of FIG. 11, and the circuit of FIG. 6 is superior to that of FIG. 10.

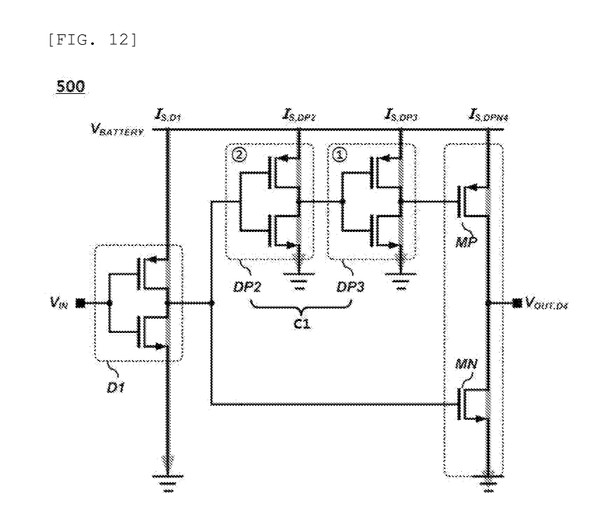

FIG. 12 is a configuration diagram of an inverter chain circuit according to a fifth exemplary embodiment of the present invention. FIG. 12 illustrates another modification example of FIGS. 9 and 11. An inverter chain circuit 500 according to the fifth exemplary embodiment includes a reference inverter D1, an inverter chain C1, a first transistor MP, and a second transistor MN.

The reference inverter D1 amplifies input signals supplied from an input port V_{IN} to output the amplified input signals, and includes N-type and P-type transistors having the same strength. That is, in the reference inverter D1, the size ratio of the P-type transistor to the N-type transistor is equal to a reference size ratio, as mentioned above. To achieve this, the size ratio of the PMOS to the NMOS constituting the inverter D1 is implemented as 2.5:1.

An output signal of the reference inverter D1 is applied to the inverter chain C1, and the inverters DP1 and DP2 including the N-type and P-type transistors are connected in multiple stages in a cascade manner.

An output signal of the inverter chain C1 is applied to a gate of the first transistor MP serving as a PMOS, and a first terminal of the first transistor is connected to a first power supply V_{BATTERY} and a second terminal thereof is connected to an output port V_{OUT,D4}. An output signal of the reference inverter is applied to a gate of the second transistor MN serving as an NMOS, and a first terminal of the second transistor is connected to a second power supply GND lower than the first power supply V_{BATTERY} and a second terminal thereof is connected to the output port. It is assumed that the size ratio of the first transistor to the second transistor is 2.5:1 and the two transistors have the same strength.

Similarly to the aforementioned exemplary embodiments, the inverter DP3 of the final stage in the inverter chain C1 is the inverter \textcircled{1} of the first group, and the inverters constituting the inverter chain C1 are connected in a cascade manner such that the inverter of the first group and the inverter of the second group are alternately connected. Accordingly, the signal applied to the gate of the first transistor MP has a duty of more than 0.5. Naturally, the signal applied to the gate of the second transistor MN remains a duty of 0.5 which is a duty of an initial input signal. In this way, by setting the duties of the input signals applied to the two transistors MP and MN to be different from each other, it is possible to prevent the two transistors MP and MN from being simultaneously turned on.

Similarly to FIG. 9, in FIG. 12, since an input impedance of the transistor MN is higher than that of the transistor MP, the transistor MN can be more easily driven than the transistor MP. Accordingly, in FIG. 12, the transistor MN directly receives a drive signal as an input from the reference inverter D1, and the transistor MP having a relatively lower input impedance is driven after additionally amplifying a power while passing through the inverters DP2 and DP3. In this case, in order to prevent the transistors MP and MN from being simultaneously turned on to cause the shoot-through currents, it is necessary to primarily adjust the input waveform of the transistor MP, and this principle is referred to the first exemplary embodiment.

According to the aforementioned exemplary embodiments of the present invention, it is possible to differently generate voltage signals applied to the NMOS and the PMOS within the inverter chain (class-D chain) constituting the supply modulator which is a device for supplying a power to the power amplifier. Accordingly, it is possible to prevent the NMOS and the PMOS from being simultaneously turned on and to minimize the shoot-through currents. As a result, it is possible to increase efficiency of the power amplifier and to minimize power consumption of the entire system.

While the present invention has been described in connection with the exemplary embodiments illustrated in the drawings, the exemplary embodiments are merely examples. It will be apparent to those skilled in the art that various modifications and equivalents to the exemplary embodiments are possible. Therefore, the technical scope of the present invention should be defined by the technical spirit of the appended claims.

1. An inverter chain circuit for controlling a shoot-through current, comprising:
first and second inverter chains to which input signals branched from an input port are individually applied, and in which inverters including N-type and P-type transistors are connected in multiple stages;
a P-type first transistor in which an output signal of the first inverter chain is applied to a gate, a first terminal is connected to a first power supply, and a second terminal is connected to an output port; and
an N-type second transistor in which an output signal of the second inverter chain is applied to a gate, a first terminal is connected to a second power supply lower than the first power supply, and a second terminal is connected to the output terminal,
wherein the first and second inverter chains are configured such that M (M is an integer equal to or greater than 2) numbers of inverters including inverters of a first group and inverters of a second group are alternately connected in a cascade manner, a size ratio of a P-type transistor to an N-type transistor being greater than a predetermined reference size ratio in the inverter of the first group, and the size ratio being smaller than the reference size ratio in the inverter of the second group, and
the inverter of the final stage in the first inverter chain is the inverter of the first group, and the inverter of the final stage in the second inverter chain is the inverter of the second group.

2. The inverter chain circuit according to claim 1, further comprising:
a reference inverter that is disposed between the input port and the two inverter chains, and amplifies the input signals to respectively apply the amplified input signals to the first and second inverter chains,
wherein the reference inverter includes N-type and P-type transistors having the reference size ratio.

3. An inverter chain circuit for controlling a shoot-through current, comprising:
an inverter chain that amplifies an input signal applied from an input port to output the amplified input signal, and includes reference inverters of multiple stages in which a size ratio of a P-type transistor to an N-type transistor is equal to a predetermined reference size ratio;
a first inverter to which an output signal of the inverter chain is applied, and in which a size ratio of a P-type transistor to an N-type transistor is larger than the predetermined reference size ratio;
a second inverter to which the output signal of the inverter chain is applied, and in which a size ratio of a P-type transistor to an N-type transistor is smaller than the reference size ratio;
a P-type first transistor in which an output signal of the first inverter is applied to a gate, a first terminal is connected to a first power supply, and a second terminal is connected to an output port; and
an N-type second transistor in which an output signal of the second inverter is applied to a gate, a first terminal is connected to a second power supply lower than the first power supply, and a second terminal is connected to the output port.

4. The inverter chain circuit according to claim 1, wherein the signal applied to the gate of the first transistor has a duty of more than 0.5, and the signal applied to the gate of the second transistor has a duty of less than 0.5.

5. The inverter chain circuit according to claim 4, wherein the size ratio of the first transistor to the second transistor is equal to the reference size ratio.

6. An inverter chain circuit for controlling a shoot-through current, comprising:
an inverter chain stage that amplifies an input signal supplied from an input port to output the amplified input signal, and includes reference inverters of multiple stages in which a size ratio of a P-type transistor to an N-type transistor is equal to a predetermined reference size ratio;
an inverter stage that amplifies the input signal to output the amplified input signal, and includes the reference inverter of one stage;
a P-type first transistor in which an output signal of the inverter chain stage is applied to a gate, a first terminal is connected to a first power supply, and a second terminal is connected to an output port; and
an N-type second transistor in which the output signal of the inverter stage is applied to a gate, a first terminal is connected to a second power supply lower than the first power supply, and a second terminal is connected to the output port.

7. An inverter chain circuit for controlling a shoot-through current, comprising:
a reference inverter that amplifies an input signal supplied from an input port to output the amplified input signal, and in which a size ratio of a P-type transistor to an N-type transistor is a predetermined reference size ratio;
an inverter chain to which an output signal of the reference inverter is applied, and in which inverters including N-type and P-type transistors are connected in multiple stages;
a P-type first transistor in which an output signal of the inverter chain is applied to a gate, a first terminal is connected to a first power supply, and a second terminal is connected to an output port; and
an N-type second transistor in which the output signal of the reference inverter is applied to a gate, a first terminal is connected to a second power supply lower than the first power supply, and a second terminal is connected to the output port,
wherein the inverter chain is configured such that M (M is an integer equal to or greater than 2) numbers of inverters including inverters of a first group and inverters of a second group are alternately connected in a cascade manner, a size ratio of a P-type transistor to an N-type transistor being greater than a predetermined reference size ratio in the inverter of the first group, and the size ratio being smaller than the reference size ratio in the inverter of the second group, and
the inverter of the final stage in the inverter chain is the inverter of the first group.

8. The inverter chain circuit according to claim 7, wherein the signal applied to the gate of the first transistor has a duty of more than 0.5.

9. The inverter chain circuit according to claim 6, wherein the size ratio of the first transistor to the second transistor is equal to the reference size ratio.

10. The inverter chain circuit according to claim 3, wherein the signal applied to the gate of the first transistor has a duty of more than 0.5, and the signal applied to the gate of the second transistor has a duty of less than 0.5.

11. The inverter chain circuit according to claim 10, wherein the size ratio of the first transistor to the second transistor is equal to the reference size ratio.

12. The inverter chain circuit according to claim 8, wherein the size ratio of the first transistor to the second transistor is equal to the reference size ratio.
